(19) United States
(12) Patent Application Publication
(10) Pub. No.: US 2024/0194454 A1
(43) Pub. Date: Jun. 13, 2024

(54) Inductively Coupled Plasma Light Source with Direct Gas Injection

(71) Applicants: Hamamatsu Photonics K.K., Shizuoka (JP); Energetiq Technology, Inc., Wilmington, MA (US)

(72) Inventors: Donald K. Smith, Newton, MA (US); Stephen F. Horne, Medford, MA (US); Michael J. Roderick, Everett, MA (US); Kosuke Saito, Hamamatsu-shi (JP); Wolfram Neff, Woburn, MA (US)

(73) Assignees: Hamamatsu Photonics K.K., Shizuoka (JP); Energetiq Technology, Inc., Wilmington, MA (US)

(21) Appl. No.: 18/077,270

(22) Filed: Dec. 8, 2022

(51) Int. Cl. H01J 37/32; H01J 37/24

(52) U.S. Cl. CPC H01J 37/32449; H01J 37/241; H01J 37/32623; H01J 37/32834

(57) ABSTRACT

An ultraviolet light source with direct feed gas injection includes a chamber comprising a plasma confinement region and defining an aperture adjacent to the plasma confinement region that passes light generated by the plasma. A magnetic core is positioned around the plasma confinement region and is configured to generate a plurality of plasma current loops that converges in the plasma confinement region during operation. A feed gas injector is coupled to a gas port in the chamber and has an output that is positioned proximate to a boundary of the plasma confinement region so that the feed gas injector provides a feed gas to the plasma confinement region that creates a differential pressure in the plasma confinement region. A high voltage region is coupled to the plasma confinement region. An exhaust port is configured to be coupled to a pump that controls a pressure in the chamber.

The section headings used herein are for organizational purposes only and should not be construed as limiting the subject matter described in the present application in any way.

### INTRODUCTION

Numerous commercial and academic applications have a need for high brightness light in the extreme ultra-violet (EUV) region of the spectrum. For example, EUV light is needed for numerous industrial applications, including photolithography, metrology, accelerated life testing, photoresist development and testing, defect inspection, and microscopy. Other applications for EUV light include spectroscopy, aerial imaging, and blank mask inspection. These and other applications require EUV sources that have high reliability, small physical size, low fixed cost, low operating cost, flexible operating space to optimize the operation to the desired application and low complexity. Known ultra-violet light sources have limited performance and usefulness in the extreme ultra-violet (EUV) region of the spectrum because of various engineering difficulties.

### SUMMARY

An ultraviolet light source with direct feed gas injection includes a chamber comprising a plasma confinement region and defining an aperture adjacent to the plasma confinement region that passed light generated by the plasma. A magnetic core is positioned around the plasma confinement region and is configured to generate a plurality of plasma current loops that converges in the plasma confinement region during operation. A high voltage region is coupled to the plasma confinement region. An exhaust port is configured to be coupled to a pump that controls a pressure in the chamber. In various configurations, a butterfly valve or other means of controlling gas conductance can be used as well as a gas controller and a variable speed vacuum pump.

A feed gas injector is coupled to a gas port in the chamber and has an output that is positioned proximate to a boundary of the plasma confinement region so that the feed gas injector provides a feed gas to the plasma confinement region that creates a differential pressure in the plasma confinement region. The feed gas injector can include a plurality of apertures that provide the feed gas into plasma confinement region. In various configurations, the output of the feed gas injector is positioned within 1 cm or within ½ cm of the boundary of the plasma confinement region. In some configurations, the output of the feed gas injector is positioned between the low voltage region and the high voltage region of the chamber.

The feed gas injector can be positioned and configured so that, during operation, a desired ratio of pressure in the plasma confinement region to pressure in the chamber proximate to the exhaust port is maintained during operation. Also, the feed gas injector can be positioned and configured so that during operation substantially all feed gas flows through the plasma confinement region before passing into the exhaust port. Also, the feed gas injector can be positioned and configured so that during operation, the gas injector injects gas into the plasma confinement region at times that refill the plasma confinement region after pinch expansion.

In some configurations, a second gas injector is included with an output that is positioned proximate to a second boundary of the plasma confinement region. The second gas injector is coupled to a second port in the chamber and can be configured to pass feed gas or another type of gas. In some configurations, the second gas injector can be configured to inject gas into the chamber at a location that provides a desired amount of back flow of gas into the plasma confinement region after formation of a pinch expansion in the plasma confinement region. Also, the second gas injector can be positioned to inject gas into the chamber so as to reduce self-absorption of the feed gas outside of the plasma confinement region.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings described below are for illustration purposes only. The drawings are not necessarily to scale; emphasis is instead generally being placed upon illustrating principles of the teaching. The drawings are not intended to limit the scope of the Applicant's teaching in any way.

FIG. 1 illustrates a known plasma chamber for generated a Z-pinch ultraviolet light.

FIG. 2 illustrates a plasma chamber for generating a Z-pinch ultraviolet light according to the present teaching.

FIG. 3 illustrates graphs of experimental data for the total output optical power generated by a known EUV light source as a function of pressure in the plasma confinement compared with experimental data for total output optical power generated by an EUV light source as a function of pressure in the plasma confinement that includes direct gas injection into the plasma generating region according to the present teaching.

FIG. 4 illustrates graphs of experimental data for the optical brightness of light generated by a known EUV light source as a function of pressure in the plasma confinement region compared with experimental data for optical brightness of light generated by an EUV light source as a function of pressure in the plasma confinement region that includes direct gas injection into the plasma generating region according to the present teaching.

FIG. 5 illustrates graphs of experimental data for beam line pressure as a function of pressure in the plasma confinement of a known EUV light source compared with experimental data for beam line pressure as a function of pressure in the plasma confinement for an EUV light source that includes direct gas injection into the plasma generating region according to the present teaching.

FIG. 6 illustrates graphs of experimental data for detected optical power as a function of pressure in the plasma confinement for a known EUV light source compared with experimental data for detected optical power as a function of pressure in the plasma confinement for an EUV light source that includes direct gas injection into the plasma generating region according to the present teaching.

### DESCRIPTION OF VARIOUS EMBODIMENTS

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications, and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the method of the present teaching can be performed in any order and/or simultaneously as long as the teaching remains operable. Furthermore, it should be understood that the apparatus and method of the present teaching can include any number or all of the described embodiments as long as the teaching remains operable.

Extreme ultraviolet (EUV) light sources play an important role in numerous optical measurement and exposure applications. It is desirable that these sources be configured to accommodate numerous use cases. One challenge is to generate high-power and high-brightness EUV light in a configuration that allows integration with numerous applications and also exhibits high stability and high reliability.

Extreme ultraviolet radiation is referred to in numerous ways by those skilled in the art. Some skilled in the art sometimes referred to extreme ultraviolet radiation as high-energy ultraviolet radiation, which can be abbreviated as EUV. Extreme ultraviolet radiation generally refers to electromagnetic radiation that is part of the electromagnetic spectrum nominally spanning wavelengths from 124 nm to 10 nm. There is some overlap between extreme ultraviolet radiation and what is considered to be the optical spectrum. One particular EUV wavelength of interest is 13.5 nm because that wavelength is commonly used for lithography. Extreme ultraviolet radiation sources, according to the present teaching, are not limited to the generation of EUV radiation. As is known in the art, plasmas can be used to generate a wide spectral range of photons. For example, plasmas generated according to the present teaching can also be used to generate soft x-ray photons (SXR). This includes, for example, photons with wavelengths of less than 10 nm.

So-called Z-pinch plasmas, which have current in the axial direction, have been shown to be effective at producing EUV and SXR light. However, most known sources have employed electrodes to conduct high discharge currents into the plasma. These electrodes, which are typically in contact with high temperature plasma, can melt and produce significant debris, which is highly undesirable as it can greatly reduce the useful lifetime of the source.

Electrodeless approaches to generated EUV are desirable and fill a considerable market need. Such sources are available, for example, from Energetiq, a Hamamatsu Company, located in Wilmington, MA. These sources are based on a Z-pinch plasma, but avoid electrodes entirely by inductively coupling current into the plasma. The plasma in these EUV sources is magnetically confined away from the source walls, minimizing the heat load and reducing debris and providing excellent open-loop spatial stability, and stable repeatable power output. One challenge with known Z-pinch light sources is that their performance, especially in brightness, is limited by their power supplies because they use magnetic switches, which are highly undesirable

One feature of the EUV sources of the present teaching is that they are versatile and support various applications with high brightness. In particular, EUV sources of the present teaching improve upon known Z-pinch designs because they can be optimized for desired power and/or for desired brightness as required by the user for a particular application. In addition, EUV sources of the present teaching have a more compact physical foot print and a more flexible component layout.

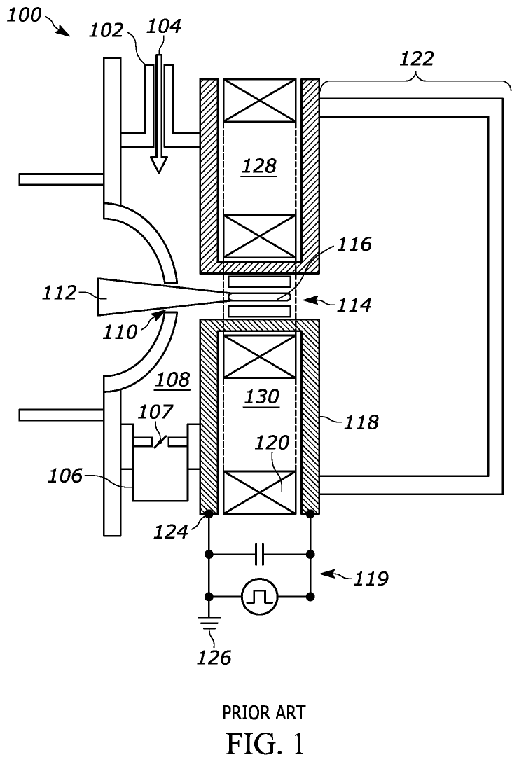

FIG. 1 illustrates a known plasma chamber 100 for generating a Z-pinch ultraviolet light. See, for example, U.S. patent application Ser. No. 17/676,712, entitled “Inductively Coupled Plasma Light Source”, which is assigned the present assignee. The entire contents of U.S. patent application Ser. No. 17/676,712 are incorporated herein by reference.

The chamber 100 includes an interface 102 that passes a feed gas 104 into the chamber 100. A pump 106 is used to evacuate the chamber region 108 to the desired operating pressure. The desired operating pressure in the chamber region 108 can be achieved by controlling the amount of gas fed into the chamber, by controlling the flow conductance of the gas into the pump, and/or by controlling the pump rate of the pump itself. For example, a butterfly valve 107 or other means of controlling gas conductance can be used as well as a gas controller and a variable speed vacuum pump. A port 110 is provided to pass EUV radiation 112 generated by the EUV plasma.

In various systems, the port 110 is configured to be adaptable for a user to attach to an application system (not shown) where the EUV radiation passes directly through the port 110. A plasma generation region 114 defines a plasma confinement region 116. The plasma confinement region 116 is formed by magnetic induction when a pulse forming and power delivery system 118 provides a current that interacts both actively and passively with magnetic cores 120, 121. A high voltage region 122 is attached to the plasma generation region 114. A grounded region 124 has an outer surface that is coupled to ground 126. A pulsed power supply 119 is electrically coupled to the power delivery system 118. The chamber 100 also includes regions 128, 130 to position magnet cores 120, 121 that provide inductive current flow for the chamber 100 in operation.

During operation of the Z-pinch plasma in this known chamber 100, the feed gas in the plasma generating region 114 is compressed by the electric pulses generated by the pulsed power supply 119, followed by an expansion of the gas after the pulse. During the compression and expansion some feed gas is lost from the plasma generating region 114 and must be replaced. This is accomplished in known EUV Z-pinched plasma light sources by simply allowing gas migrating into the plasma generating region from the area surrounding the plasma generating region.

One aspect of the present teaching is the realization that the slow replenishment of gas into the plasma generating region from the area surrounding the plasma generating region in known EUV Z-pinched plasma light sources severely limits the performance of known EUV Z-pinched plasma light sources. Another aspect of the present teaching is the understanding that the performance of known extreme ultraviolet radiation sources that use Z-pinched plasmas can be greatly improved by using a direct gas feed system and method to inject feed gas directly into the plasma generating region so that there are no significant time delays in replenishing gas into the plasma generation region when needed to achieve the desired light source performance or to at least create operating conditions that are not feed gas limited.

Such direct gas feeding into the plasma generating region can be accomplished by providing a separate gas tube structure or an integrated tunnel structure that delivers gas directly from a gas source through the chamber to a region that is in contact or that is in close proximity with a boundary of the plasma generating region without gas leakage. In various embodiments, the gas tube structure comprises one or a plurality of apertures that provide feed gas to the plasma generating region. Also, in various embodiments, the plasma generating region and the structure surrounding it may be split in separate sections that are spaced apart to allow the target gas to enter the plasma generating region in the gap between the sections. The result is that the target gas used in the process is forced to enter the chamber directly through the plasma generating region. This feature of the present teaching allows operation at pulse rates that would otherwise be prohibited by the slow migration of gas back into the plasma generating region after a Z-pinch compression.

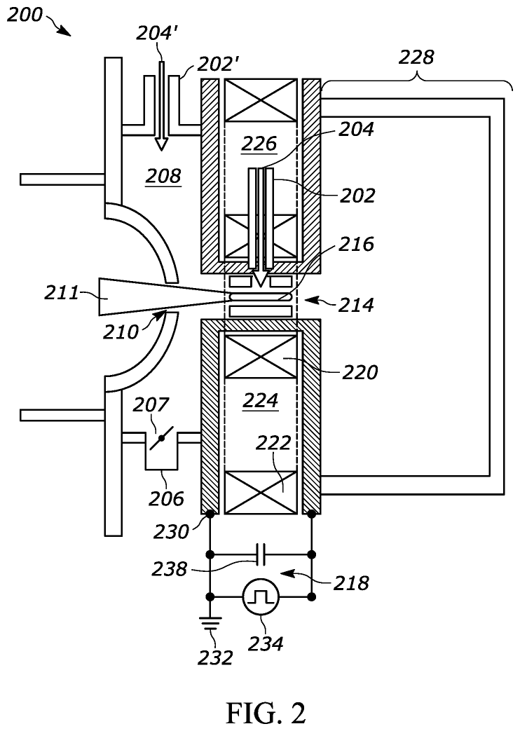

FIG. 2 illustrates a plasma chamber 200 for generating a Z-pinch ultraviolet light according to the present teaching. The chamber 200 is similar to the chamber 100 described in connection with FIG. 1, however, the chamber 200 includes a direct gas feeding apparatus according to the present teaching. The chamber 200 includes an interface 202 that passes a feed gas 204 into the chamber 200. The interface 202 can be a gas tube structure that is separate from the chamber 200 or can be an integrated tunnel structure that is formed directly in the chamber 200. The interface 200 delivers gas directly from a gas source through the chamber 200 to a region that is in contact or that is in close proximity with a boundary of the plasma generating region without gas leakage.

Some embodiments include a second interface 202′ that passes feed gas 204′ and/or a second gas into the chamber a second location. A pump 206 is used to evacuate the chamber region 208 to the desired operating pressure. The desired operating pressure in the chamber region 208 can be achieved by controlling the amount of gas fed into the chamber, by controlling the flow conductance of the gas into the pump, and/or by controlling the pump rate of the pump itself. For example, a butterfly valve 207 or other means of controlling gas conductance can be used as well as gas controller and a variable speed vacuum pump.

A port 210 is provided to pass EUV radiation 211 generated by the EUV plasma. The port 210 can include an EUV output port that passes the desired EUV radiation and substantially blocks other wavelengths of radiation. The port 210 can be configured to include a filter structure that blocks undesired radiation. In some embodiments, the port 210 is configured to be opaque to visual light. For example, in various embodiments, the EUV transparent port 210 is an aperture that can include a spectral purifying foil. Typically, the port 210 is a beamline aperture port that passes radiation propagating along the beamline. The port 210 can also be configured to have a desired diameter so as to physically block light propagating in certain directions. Furthermore, the diameter of an aperture that defines the port 210 can be chosen to provide a desired pressure differential between the outside and inside of the chamber 200.

In various systems, the port 210 is configured to be adaptable for a user to attach to an application system (not shown) where the EUV radiation passes directly through the port 210. A plasma generation region 214 defines a plasma confinement region 216. The plasma confinement region 216 is formed by magnetic induction when a pulse forming and power delivery section 218 provides a current that interacts both actively and passively with magnetic cores 220, 222 that are positioned in regions 224, 226 so that inductive current flows in the chamber 200 during operation. The magnetic confinement of the plasma in the plasma confinement region 216 is beneficial because the plasma is kept away from the components in the chamber 210, causing less erosion and associated contamination, which improves reliability and stability for the light source.

A high voltage region 228 is attached to the plasma generation region 214. A grounded region 230 has an outer surface that is coupled to ground 232. A pulsed power supply 234 is electrically coupled to the power delivery section 218 that is coupled to the high voltage region 228 and to the grounded region 230. The pulsed power supply 234 includes a parallel connected capacitor 238. In many embodiments, the capacitor 238 is a bank of multiple capacitors. The pulse generator 234 applies negative high-voltage pulses across the capacitor 238 and drives a current through the power delivery section 218 to ground 226.

Thus, the power delivery section 218 of the chamber 200 has a high voltage side 228 and a ground side 230. At least three inductively coupled plasma loops (not shown) are formed from the current pulses flowing through power delivery section 218 that interact both actively and passively with magnetic cores 220, 221. The plasma loops converge in the plasma generation region 214 that forms a magnetically confined Z-pinch. The plasma loops flow through the region between the inner core 220 and outer core 222 and through the plasma generation region 214.

One skilled in the art will appreciate that there are numerous methods of generating ultraviolet light according to the present teaching. These methods generally provide a feed gas to a boundary of the plasma confinement region in a plasma chamber. The feed gas is provided to the interface 202 that directly injects the feed gas 204 into the chamber 200 at the boundary of the plasma generation region 214. In some methods of operation, the feed gas is Xenon. In some methods of operation, the feed gas is Argon, Nitrogen, Neon, Helium, or a combination of gases that have light emission at the desired wavelength. Also, in some methods of operation, the mixture of feed gases is chosen so that the gas mixture provides desired light emission characteristics or increased optical power stability. For example, it can be beneficial to introduce Helium into the chamber to improve pinch stability without diluting the target gas in the plasma generating region. Introduction of a second gas or additional gases in the chamber may also further reduce self-absorption in the chamber.

It should be understood that some methods also apply feed gas and/or other gases to the second interface 202′ positioned at one or more of various locations in the chamber 200, such as adjacent to the plasma generating region but not at a boundary.

The pulse power supply 234 generates voltage pulses. A train of voltage pulses is applied to at least one capacitor 238 electrically connected across an outer magnetic core 222 surrounding an inner magnetic core 220 that is positioned around the plasma confinement region 214. The outer core 222 eventually saturates, driving the impedance to zero. That is, the voltage pulses cause the at least one capacitor 238 to charge so that the outer magnetic core 222 saturates resulting in the capacitor(s) discharging causing the inner core 220 to couple the current pulse to the plasma loops, which results in a large pulse in plasma current driving the Z-pinch. During the charging time, a small leak current from the cores 220, 222 sustains the plasma loops. The Z-pinch operation requires a sustained loop, because it requires continuous ionized gas for proper function.

During operation of the Z-pinch plasma in chamber 200, the feed gas in the plasma generating region 214 is compressed by the electric pulses generated by the pulsed power supply 234, followed by an expansion of the gas after the pulse. In contrast to known chambers for producing EUV light, during the pulse compression and expansion, feed gas is provided directly to the plasma generating region 214 with a flow rate and volume that provides sufficient feed gas to replenish feed gas lost from pulse compression to form the Z-pinched plasma. Importantly, with the configuration shown in FIG. 2, no gas flows directly from the feed gas inlet 204 to the vacuum pump 206 without passing through the plasma generating region.

As a result, the plasma generation region 214 produces and emits nearly 100% of the EUV radiation produced by the plasma. The plasma loops themselves do not produce EUV light. The result is that the source 200 produces a high quality, relatively compact source of EUV light from a well-defined and stable Z-pinch plasma confinement region 216 within the plasma generation region 214. One feature of the present teaching is that by using the pulse forming and power delivery section 218 to drive and contain the plasma in the Z-pinch plasma confinement region 216, the source 200 operates without the use of electrodes that are commonly used to conduct discharge current to the plasma in known systems.

There are numerous advantages to the method and apparatus of direct feed gas injection in the plasma confinement regions of light sources according to the present teaching. First, direct feed gas injection under proper flow rates eliminates performance limitations of the light source that result from insufficient feed gas molecules being present in the plasma generation area the chamber. In addition, direct feed gas injection more efficiently uses the feed gas because unused gas does not flow directly from the feed gas inlet 204 to the vacuum pump 206 without passing through the plasma generating region. The direct injection significantly reduces the operational costs of the light source as overall significantly less feed gas is required to achieve the same operating conditions as known EUV light sources. This is especially beneficial for an expensive target gas like Xe.

In addition, another feature of the present teaching is the realization that the direct injection of the feed gas reduces self-absorption of EUV light generated in plasma confinement region 214 as a result of the pressure differential between the plasma generating region and the other regions of the chamber. The following example is useful to illustrate this feature. Assuming the desired operating pressure for the plasma generating region 214 is 100 mTorr, the pressure in the plasma generating region 214 in known EUV light sources has to be at least 100 mTorr. Consequently, to reach 100 mTorr in the plasma generating region 214 without direct injection, the pressure proximate to the plasma generating region 214 would likely need to be more than 100 m Torr because of flow restrictions to the plasma generating region and because of the presence of higher conductance proximate to the plasma generating region 214. The resulting pressure differential between the plasma generating region 214 and the surrounding area reduces the amount of light generated by the light source through self-absorption.

In contrast, directly feeding gas at a pressure of 100 mTorr into the plasma generating region may be achieved without requiring the rest of the system being at the same pressure. A significantly lower pressure, for example 50 mTorr, can be sufficient. In this example, the adjacent chamber pressure may be less than 5 mTorr. Thus, with these pressures, the loss by self-absorption would be significantly reduced.

In addition, another feature of the present teaching is that the plasma generating region will have less contamination because the predominant material flow is from the plasma generating region towards the area surrounding the plasma generating region. This is in contrast to known EUV light sources where gas flows from the surrounding areas into the plasma generating regions. In the typical configuration without the direct feeding gas of the present teaching, the material entering the plasma generating region may be a mix of the target gas and contamination. Such prior art methods will transport contamination from the sounding areas into the plasma generating regions.

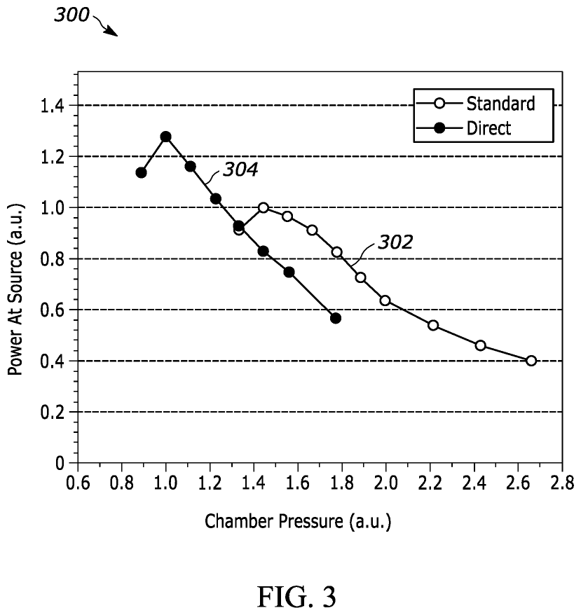

FIG. 3 illustrates graphs 300 of experimental data for the total output optical power generated by a known EUV light source as a function of pressure in the plasma confinement compared with experimental data for total output optical power generated by an EUV light source as a function of pressure in the plasma confinement that includes direct gas injection into the plasma generating region according to the present teaching. The output optical powers are measured at the source output. The pressure is measured at an area surrounding the plasma generating region. The data was taken with the same chamber configuration, geometry, and with the sources operating under the same parameters.

More specifically, the graph 302 illustrates total output optical power generated by a known EUV light source as a function of pressure in the plasma confinement region where a Z-pinch is generated. Graph 304 illustrates total output optical power generated by an EUV light source that includes direct gas injection into the plasma generating region as a function of pressure in the plasma confinement region where a Z-pinch is generated. The data from graphs 302 and 304 illustrate that the optical power generated by the EUV light sources of the present teaching is approximately 28% higher than the optical power generated by known systems with the same chamber configuration, geometry, and with the light sources operating under the same parameters. In addition, the data from graphs 302 and 304 illustrate that the EUV light source according to the present teaching that includes direct gas injection into the plasma generation region has the highest power output at lower pressures in the area surrounding the plasma generating region. This is advantageous because lower pressures reduce loss of light from self-absorption.

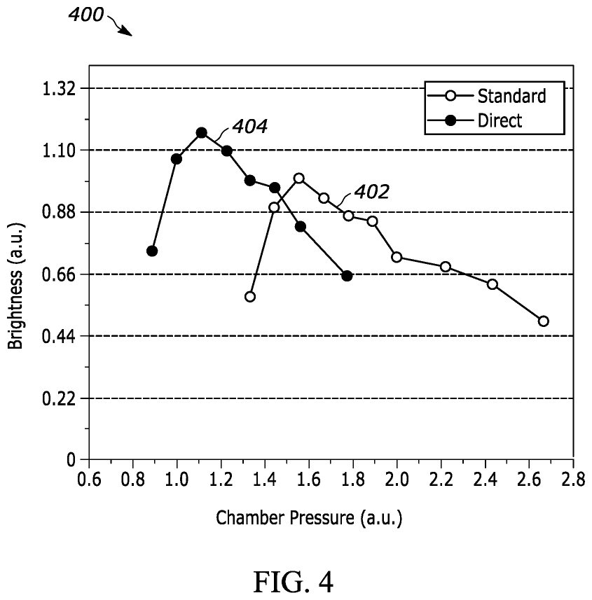

FIG. 4 illustrates graphs 400 of experimental data for the optical brightness of light generated by a known EUV light source as a function of pressure in the plasma confinement region compared with experimental data for optical brightness of light generated by an EUV light source as a function of pressure in the plasma confinement region that includes direct gas injection into the plasma generating region according to the present teaching. The output optical powers are measured at the source output. The pressure is measured at an area surrounding the plasma generating region. The data was taken with the same chamber configuration, geometry, and with the sources operating under the same parameters.

More specifically, the graph 402 illustrates optical brightness generated by a known EUV light source as a function of pressure in the plasma confinement region where a Z-pinch is generated. Graph 404 illustrates optical brightness generated by an EUV light source that includes direct gas injection into the plasma generating region as a function of pressure in the plasma confinement region where a Z-pinch is generated. The data from graphs 402 and 404 illustrate that the optical brightness generated by the EUV light sources of the present teaching is approximately 11% higher than the brightness generated by known system with the same chamber configuration, geometry, and with the light sources operating under the same parameters. In addition, the data from graphs 402 and 404 illustrate that the EUV light source according to the present teaching that includes direct gas injection into the plasma generation region has higher and maximum brightness at lower pressures. This is also advantageous because lower pressures reduce loss of light from self-absorption.

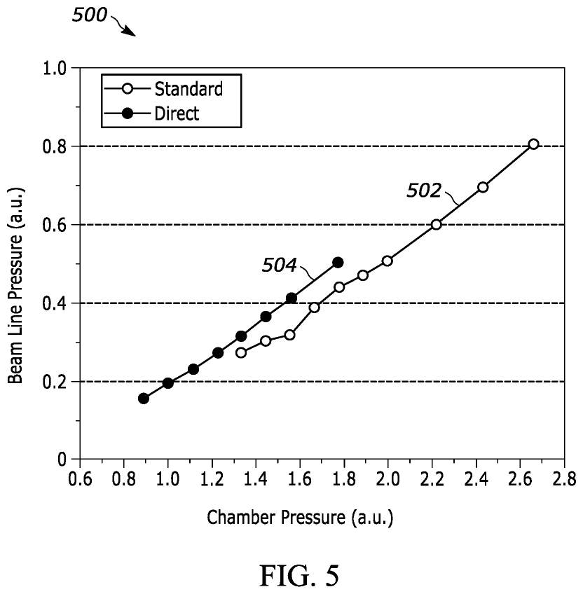

FIG. 5 illustrates graphs 500 of experimental data for beam line pressure as a function of pressure in the plasma confinement of a known EUV light source compared with experimental data for beam line pressure as a function of pressure in the plasma confinement for an EUV light source that includes direct gas injection into the plasma generating region according to the present teaching. The beam line pressure is the pressure in an attached system that couples the light generated by the EUV light source into system for some particular application.

More specifically, the graph 502 illustrates experimental data for beam line pressure as a function of pressure in the plasma confinement of a known EUV light source. The graph 504 illustrates experimental data for beam line pressure as a function of pressure in the plasma confinement for an EUV light source that includes direct gas injection into the plasma generating region according to the present teaching. The data from graphs 502 and 504 illustrate that beam line pressure as a function of pressure in the plasma confinement for an EUV light source that includes direct gas injection into the plasma generating region according to the present teaching is lower for all operating conditions observed for the EUV light source that includes direct gas injection into the plasma generating region according to the present teaching. This is advantageous because attached application system needs to maintain a low pressure since gas in the application system absorbs some of the light generated by the source.

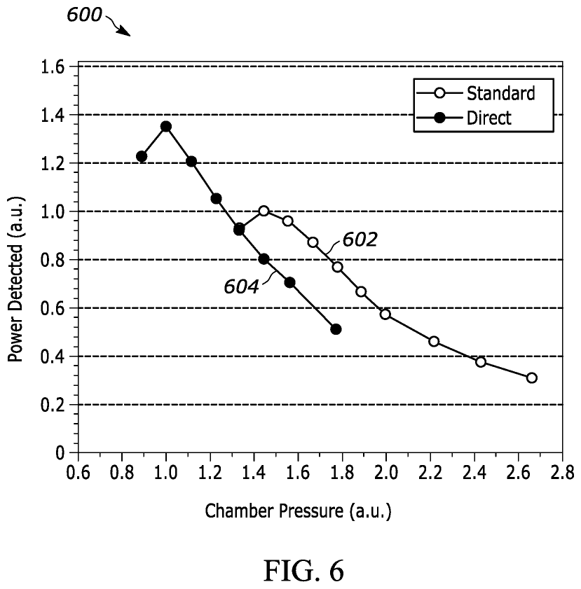

FIG. 6 illustrates graphs 600 of experimental data for detected optical power as a function of pressure in the plasma confinement for a known EUV light source compared with experimental data for detected optical power as a function of pressure in the plasma confinement for an EUV light source that includes direct gas injection into the plasma generating region according to the present teaching. The output optical powers are measured at the detector position. The pressure is measured at an area surrounding the plasma generating region. The data was taken with the same chamber configuration, geometry, and with the sources operating under the same parameters.

More specifically, the graph 602 illustrates experimental data for detected optical power as a function of pressure in the plasma confinement for a known EUV light source. The graph 604 illustrates experimental data for detected optical power as a function of pressure in the plasma confinement for an EUV light source that includes direct gas injection into the plasma generating region according to the present teaching. The data in graph 604 corresponding to the EUV light sources that includes direct gas injection into the plasma generating region according to the present teaching shows the effect of the reduced self-absorption in the attached application system from the power measured at the detector location.

In particular, the data in graph 604 shows that by providing the feed gas directly to the plasma generating region there is an approximately 35% higher light output detected than with known systems with the same chamber configuration, geometry, and with the sources operating under the same parameters. With EUV light sources according to the present teaching, the target gas is delivered more efficiently to the plasma generation region at higher pressures so the source can be operated at a higher repetition rate, which results in increased EUV output

Thus, an important feature of the EUV light sources with direct gas injection according to the present teaching is that such light sources shift the operating optimum performance point towards lower pressure ranges in the plasma confinement region. This shift towards lower pressure in the plasmas confinement regions results in a reduction of pressure in the application system as well as reduced optical absorption.

The following example is helpful in illustrating performance that can be achieved with an EUV light source with direct gas feeding according to the present teaching. Referring back to FIG. 2, experiments have determined that the source 200 can be configured and operated with operating conditions that produce about twenty Watts of 13.5-nm-wavelength EUV radiation in 2-pi steradians with a brightness of eight W/mm²-sr. The pulse rate of the source was adjustable. For example, the pulse rate was 2.5 kHz in some experiments recording these data. Under these conditions, the plasma confinement region 214 was less than 1 mm in diameter and was even made to be less than 0.5 mm in diameter by changing some operating conditions. In some methods of operation, the actual position of the plasma confinement region 214 was made to vary by less than a few microns pulse-to-pulse.

These data in the experimental results indicate that EUV sources that use direct gas feeding according to the present teaching are useful for wide array of test and measurement systems. The EUV source with direct gas injection according to the present teaching can provide highly flexible access to the EUV radiation generated by the plasma that results in many more possible application configurations than known EUV systems because of the lower pressure operation. Also, the EUV source with direct gas injection according to the present teaching can provide highly flexible access to the EUV radiation generated by the plasma that results in many more possible application configurations than known EUV systems also because of the resulting reduced self-absorption. In addition, the EUV source with direct gas injection according to the present teaching can provide highly flexible access to the EUV radiation generated by the plasma that results in many more possible application configurations than known EUV systems because of the wider range of operation conditions. Furthermore, the EUV source with direct gas injection according to the present teaching can provide highly flexible access to the EUV radiation generated by the plasma that results in many more possible application configurations than known EUV systems also because it provides more flexibility over the size and shape of the Z-pinched plasma.

Thus, an EUV light source according to the present teaching provides numerous performance advantages by providing a gas feed directly to the plasma generation region so that gas does not need to migrate into the plasma generating region from the vacuum chamber. This feature is desirable especially when an increase in total delivered EUV output requires a pulse rate that is on order of 2,500 Hz. Under these and similar conditions, the slow refeeding of the plasma generating region leads to a performance decrease in known EUV light sources. With direct gas feeding, since the feed gas is forced directly through the plasma generating region, the feed gas does not have to migrate there, and a re-filling of the plasma generating region is faster and more efficient. This allows an operation of the plasma light source at repetition rates exceeding what can be achieved if direct gas feeding is not used. Additional benefits are reduced self-absorption and higher gas utilization, and the ability to introduce different gas species at a plurality of different locations.

### EQUIVALENTS

While the Applicant's teaching is described in conjunction with various embodiments, it is not intended that the Applicant's teaching be limited to such embodiments. On the contrary, the Applicant's teaching encompasses various alternatives, modifications, and equivalents, as will be appreciated by those of skill in the art, which may be made therein without departing from the spirit and scope of the teaching.

What is claimed is:

1. An ultraviolet light source with direct feed gas injection, the light source comprising:
a) a chamber comprising a plasma confinement region and defining an aperture adjacent to the plasma confinement region that passes light generated by the plasma;
b) a magnetic core positioned around the plasma confinement region and configured to generate a plurality of plasma current loops that converges in the plasma confinement region during operation;
c) a feed gas injector coupled to a gas port in the chamber and having an output positioned proximate to a boundary of the plasma confinement region, the feed gas injector providing a feed gas to the plasma confinement region that creates a differential pressure in the plasma confinement region;
d) a high voltage region coupled to the plasma confinement region; and
e) an exhaust port that is configured to be coupled to a pump that controls a pressure in the chamber.

2. The light source of claim 1 wherein the output of the feed gas injector is positioned within 1 cm of the boundary of the plasma confinement region.

3. The light source of claim 1 wherein the output of the feed gas injector is positioned within ½ cm of the boundary of the plasma confinement region.

4. The light source of claim 1 wherein the output of the feed gas injector is positioned between a low voltage region and the high voltage region of the chamber.

5. The light source of claim 1 wherein the feed gas injector comprises a gas tube having an output that is positioned proximate to the boundary of the plasma confinement region.

6. The light source of claim 1 wherein the feed gas injector is formed in the chamber.

7. The light source of claim 1 wherein the feed gas injector comprises a plurality of apertures that provide the feed gas into plasma confinement region.

8. The light source of claim 1 wherein the feed gas injector is positioned so that substantially all feed gas flows through the plasma confinement region before passing into the exhaust port.

9. The light source of claim 1 wherein the feed gas injector is positioned and configured so that a desired ratio of pressure in the plasma confinement region to pressure in the chamber proximate to the exhaust port is maintained during operation.

10. The light source of claim 1 further comprising a second gas injection port.

11. The light source of claim 10 wherein the second gas injection port is positioned proximate to the high voltage region.

12. The light source of claim 10 wherein the second gas injection port is positioned proximate to a low voltage portion of the chamber.

13. The light source of claim 10 wherein the second gas injection port is configured to introduce a second type of feed gas.

14. The light source of claim 10 wherein the second gas injection port comprises an output that is positioned proximate to a second boundary of the plasma confinement region.

15. The light source of claim 10 further comprising a second feed gas injector coupled to the second gas injection port and having an output positioned in the second boundary of the plasma confinement region.

16. The light source of claim 10 wherein the second gas injection port is configured to inject gas into the chamber at a location that provides a desired amount of back flow of gas into the plasma confinement region after formation of a pinch expansion in the plasma confinement region.

17. The light source of claim 10 wherein the second gas injection port is positioned to inject gas into the chamber so as to reduce self-absorption of the feed gas outside of the plasma confinement region.

18. The light source of claim 1 wherein the feed gas injector comprises a pulsed gas injector configured to inject gas into the plasma confinement region at times that refill the plasma confinement region after pinch expansion.

19. A method of generating ultraviolet light, the method comprising:
a) providing a chamber that defines a plasma confinement region therein, the chamber defining a port that passes plasma generated light out of the chamber, a high voltage region coupled to the plasma confinement region, and an exhaust port that is configured to be coupled to a vacuum pump that controls a pressure in the chamber;
b) directly injecting a feed gas into a boundary of the plasma confinement region;
c) providing voltage to the high voltage region, thereby generating a plasma; and
d) controlling a pressure in the plasma confinement region relative to the chamber so as to provide a desired pressure differential

20. The method of claim 19 wherein the controlling the pressure in the plasma confinement region relative to the chamber comprises controlling a flow of the feed gas with a mass flow controller.

21. The method of claim 19 further comprising injecting a feed gas in the chamber.

22. The method of claim 21 wherein the feed gas injected into the chamber is injected proximate to the high voltage region.

23. The method of claim 21 wherein the feed gas injected into the chamber is injected proximate to a low voltage region.

24. The method of claim 19 further comprising adjusting a flow of the feed gas injected into the chamber so as to provide a desired amount of back flow of gas into the plasma confinement region after formation of a pinch expansion in the plasma confinement region.

25. The method of claim 19 further comprising injecting a second feed gas directly into a second boundary of the plasma confinement region.

26. The method of claim 19 wherein the directly injecting the feed gas into the boundary of the plasma confinement region comprises injecting the feed gas through a tube having an output positioned inside of the boundary of the plasma confinement region.

27. The method of claim 19 wherein the directly injecting the feed gas into the boundary of the plasma confinement region comprises injecting the feed gas in a plurality of locations inside of the boundary of the plasma confinement region.

28. The method of claim 19 further comprising configuring the chamber so that substantially all the feed gas flows through the plasma confinement region before passing into the exhaust port.

29. The method of claim 19 further comprising pumping the chamber through an exhaust port to provide a desired ratio of pressure in the plasma confinement region to pressure in the chamber proximate to the exhaust port.

30. The method of claim 19 further comprising adjusting a flow of the feed gas directly injected into the boundary of the plasma confinement region so as to provide a desired ratio of pressure in the plasma confinement region to pressure in the chamber proximate to an exhaust port.

31. The method of claim 19 wherein the directly injecting the feed gas into the boundary of the plasma confinement region comprises injecting gas into the plasma confinement region at times that refill the plasma confinement region after pinch expansion.

32. The method of claim 19 wherein the directly injecting the feed gas into the boundary of the plasma confinement region comprises injecting the feed gas at a flow rate that reduces self-absorption of the feed gas outside of the plasma confinement region.
